(19) United States
(12) Patent Application Publication
(10) Pub. No.: US 2002/0021593 A1
(43) Pub. Date: Feb. 21, 2002

(54) Semiconductor memory device with a redundancy structure

(75) Inventor: Takaharu Tsuji, Hyogo (JP)

Correspondence Address: McDERMOTT, WILL & EMERY, 600 13th Street, N. W., Washington, DC, 20005-3096, US

(73) Assignee: Mitsubishi Denki Kabushiki Kaisha

(21) Appl. No.: 09/768,352

(22) Filed: Jan. 25, 2001

(30) Foreign Application Priority Data
Aug. 21, 2000 (JP) 2000-249463 (P)

(51) Int. Cl. G11C 29/00

(52) U.S. Cl. 365/200

(57) ABSTRACT

A semiconductor memory device that can transfer data at high speed is provided. The semiconductor memory device includes a memory cell array, a normal data line pair, a redundant data line pair and a data line switch circuit. The data line switch circuit includes an IO shift decoder decoding the column address and the position information related to a defective data line, and an IO select unit shifting the connection between a data input/output pin and a data line while replacing the defective data line according to the decoded result. High speed data transfer is realized by carrying out simultaneously data line selection and redundancy selection according to the column address.

### BACKGROUND OF THE INVENTION

1. Field of the Invention

The present invention relates to semiconductor memory devices, particularly to a semiconductor memory device having a redundancy structure.

2. Description of the Background Art

In order to repair defective memory cells to improve the yield, a conventional semiconductor memory device includes redundant memory cells to substitute for the defective memory cell.

In recent years, the demand for a large bus width to improve the data transfer speed is great. There is the tendency of a larger data line width and a relatively smaller column address. Particularly in a dynamic random access memory (DRAM) embedded with a logic circuit directed to system-on-chip, there is the demand of increasing the bus width from 32 bits to 256 bits and reducing the column address from 256 bits to 16 bits.

In a conventional semiconductor memory device, repair of a defective memory cell was carried out by exchanging the bit lines through a column address. When the column address is small, a high repair rate cannot be achieved unless a relatively large amount of redundant memory cells are prepared.

To this end, the method of arranging a redundant memory cell and a redundant data line connected to that redundant memory cell to exchange the defective data line with a redundant data line is being employed.

In a logic-embedded DRAM, the method is employed of providing a large internal bus width and selecting a required bus width using a column address at the connection to an external source so as to accommodate a variety of bus widths.

An example of a conventional semiconductor memory device 5000 with a redundancy structure will be described with reference to FIG. 29. Semiconductor memory device 5000 includes a memory cell array 500 with a plurality of memory cells arranged in a matrix, a plurality of normal data line pairs 501 connected to memory cells via a sense amplifier, a redundant data line pair 502, a row decoder 510 decoding an input row address to carry out selection in a row direction, a column address decoder 511 decoding an input column address for output, a shift redundancy circuit 512 including position information of a defective data line, an IO select circuit 503 selecting a data line, a read amplifier.write driver unit 504, and an IO shift circuit 505.

IO select circuit 503 selects a data line pair to be used according to the output of column address decoder 511. Referring to FIG. 30, IO select circuit 503 is formed of a plurality of switches. Half of normal data line pairs LIO(0), /LIO(0), . . . are connected to read amplifier.write driver unit 504. Redundant data line pair SLIO(0), /SLIO(0) or SLIO(1), SLIO(1) is connected to read amplifier.write driver unit 504.

Read amplifier.write driver unit 504 includes a plurality of read amplifier.write drivers RW (read amplifier R, write driver W). By read amplifier.write driver unit 504, the data of the selected data line pair are transmitted to internal data lines DB(0), . . . and redundant internal data line SDB, or the data of internal data lines DB(0), . . . and redundant internal data line SDB are transmitted to the selected data line pair.

In IO shift circuit 505, the connection between the internal data line and the data input/output pin (external data line) is shifted to remove a defective data line according to the data line shift method, as shown in FIG. 31. More specifically, the defective data line is replaced with an adjacent data line. The data line used for replacement is further replaced with an adjacent data line. By repeating replacement between adjacent data lines, the last data line is replaced with the redundant data line. As a result, data lines other than the defective data line are connected to data input/output pins (external data line) DQ(0)-DQ(n).

Thus, data of a selected memory cell is output to an external source. In a write operation, data is written into a selected memory cell through an opposite path.

According to the structure of the conventional semiconductor memory device, the pass through the switch circuit to switch the data lines and the data line switch circuit for redundancy replacement is inevitable, causing delay in data transfer.

### SUMMARY OF THE INVENTION

In view of the foregoing, an object of the present invention is to provide a semiconductor memory device capable of high speed data transfer in a semiconductor memory device having a redundancy structure.

According to an aspect of the present invention, a semiconductor memory device includes a memory cell array with a plurality of memory cells arranged in a matrix, a plurality of data lines with a redundant data line and a normal data line to read out data or write in data from/to the memory cell array, a plurality of external data lines to transfer data with an external source, and a data line switch circuit executing simultaneously a select operation of selecting a data line to be coupled with a plurality of external data lines and a shift operation of shifting the connection of a data line to be coupled to a plurality of external data lines according to an external address and data line information related to a defective data line in the normal data lines.

Preferably, the plurality of data lines are divided into a plurality of blocks. The data line switch circuit includes a decoder decoding an external address and data line information, and a plurality of select circuits arranged between a plurality of blocks and the plurality of external data lines respectively. Each of the plurality of select circuits carries out a select operation and a shift operation simultaneously according to the output of the decoder. Each of the plurality of select circuits shares some of the data lines with an adjacent select circuit.

Each of the plurality of select circuits includes a plurality of transfer gates provided between a corresponding data line and a corresponding external data line to be open/closed according to the output of the decoder.

According to the semiconductor memory device having a redundant data line of the present aspect, execution of the data line shift redundancy scheme and selection of a data line specified by an address can be carried out simultaneously. Therefore, high speed data transfer is allowed.

According to another aspect of the present invention, a semiconductor memory device includes a memory cell array with a plurality of memory cells arranged in a matrix, a plurality of data lines with a redundant data line and a normal data line to read out or write in data from or to the memory cell array, and a data line switch circuit executing simultaneously a select operation of selecting a data line to be coupled with a plurality of external data lines according to an external address and a replace operation of replacing a defective data line in the data line to be coupled with a redundant data line according to data line information related to a defective data line.

Preferably, the plurality of normal data lines are divided into a plurality of blocks. The data line switch circuit includes a decoder decoding an external address and data line information, and a plurality of select circuits. Each of the plurality of select circuits carries out simultaneously a select operation and a replace operation.

Particularly, each of the plurality of select circuits includes a plurality of transfer gates that are open/closed according to the output of the decoder, provided between a redundant data line and corresponding normal data line and a corresponding external data line.

According to the semiconductor memory device having a redundant data line of the present aspect, data transfer can be carried out at high speed since the data line replace operation and the data line select operation are carried out simultaneously.

According to a further aspect of the present invention, a semiconductor memory device includes a memory cell array with a plurality of memory cells arranged in a matrix, a plurality of data lines with a redundant data line and a normal data line to read out or write in data from or into the memory cell array, and a data line switch circuit executing simultaneously a select operation of selecting a data line to be coupled with an external data line to be used according to a bus width and a shift operation of shifting connection between the external data line to be used and the data line to be coupled according to data line information related to a defective data line in the normal data line.

Preferably, each of the plurality of data lines and plurality of external data lines is divided into a plurality of blocks. The plurality of blocks share some data lines with an adjacent block. The data line switch circuit includes a plurality of switch circuits arranged corresponding to the plurality of blocks, respectively. Each of the plurality of switch circuits belongs to any of the status of a mode switching the connection between a corresponding data line and a corresponding external data line according to a bus width, a mode of substituting the defective data line with a common data line, and shifting connection between a corresponding external data line and a corresponding data line according to the bus width, and a mode of shifting connection between a corresponding data line and a corresponding external data line according to the bus width.

Particularly, each of the plurality of switch circuits includes m nodes, a first gate selectively switching the connection between the m nodes and m external data lines according to the bus width, a second gate rendering a defective data line and m nodes nonconnected according to the bus width and data line information, and a third gate selectively connecting a common data line with one of the m nodes according to the bus width and the data line information.

According to the semiconductor memory device of the present aspect, the data line select circuit and the redundant replacement circuit are shared in common. The shift redundancy scheme is employed in combination on a block-by-block basis to switch the bus width. Therefore, data can be transferred at high speed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing schematically a structure of a semiconductor memory device 1000 according to a first embodiment of the present invention.

FIG. 2 is a block diagram to describe a structure of an 10 select unit 107 of the first embodiment.

FIG. 3 is a diagram to describe a 1/4 select circuit and a shift decoder according to the first embodiment.

FIG. 4 is a diagram to describe the operation of shift decoders SXi and SYi of the first embodiment.

FIG. 5 is a diagram to describe the relationship between a defective data line identify signal FS(i) and a defective data line.

FIG. 6 shows a signal applied to each 1/4 select circuit when a normal data line LIO(3) is defective in the first embodiment.

FIG. 7 is a block diagram schematically showing a structure of a semiconductor memory device 1500 according to a second embodiment of the present invention.

FIG. 8 is a block diagram to describe a structure of an IO select unit 157 according to a second embodiment of the present invention.

FIG. 9 is a diagram to describe a 1/4 select circuit and a decoder according to the second embodiment.

FIG. 10 is a diagram to describe an operation of decoders SZi and SWi according to the second embodiment.

FIG. 11 is a diagram to describe the relationship between a defective data line replace signal RS(i) and a defective data line.

FIG. 12 shows a signal input to each 1/4 select circuit when a normal data line LIO(3) is defective in the second embodiment.

FIG. 13 is a block diagram schematically showing the structure of a semiconductor memory device 2000 according to a third embodiment of the present invention.

FIG. 14 shows the relationship among the bus width, column address and address decode signal YSEL<3:0>.

FIG. 15 shows the relationship between the bus width and an external data line (data input/output pin) to be used.

FIG. 16 is a block diagram showing an example of a structure of an IO select circuit Zk in an IO select unit 204.

FIG. 17 shows a structure of an IO switch circuit 210.

FIG. 18 is a circuit diagram showing a structure of a transfer gate.

FIG. 19 shows the relationship between the data bus and switch change.

FIG. 20 shows the relationship among a block including a defective data line, signal USEL<7:0>, and the status signal of each block.

FIG. 21 is a circuit diagram showing an example of a structure of a redundancy mode decode circuit 211.

FIGS. 22-24 are diagrams to describe the operation of an IO line switch signal generation circuit 212.

FIG. 25 shows the relationship between the position of the defective data line and signal LSEL<3:0>.

FIG. 26 shows a circuit 260 in IO line switch signal generation circuit 212.

FIG. 27 shows a circuit 270 in IO line switch signal generation circuit 212.

FIG. 28 is a diagram showing an example of an operation of semiconductor memory device 2000 of the third embodiment.

FIG. 29 is a block diagram schematically showing a structure of a conventional semiconductor memory device 5000.

FIG. 30 is a diagram to describe schematically the structure of a conventional IO select circuit 503.

FIG. 31 schematically shows a structure of a conventional IO shift circuit 505.

### DESCRIPTION OF THE PREFERRED EMBODIMENTS

Embodiments of the semiconductor memory device of the present invention will be described with reference to the drawings. In the drawings, corresponding or likewise components have the same reference characters allotted, and description thereof will not be repeated.

First Embodiment

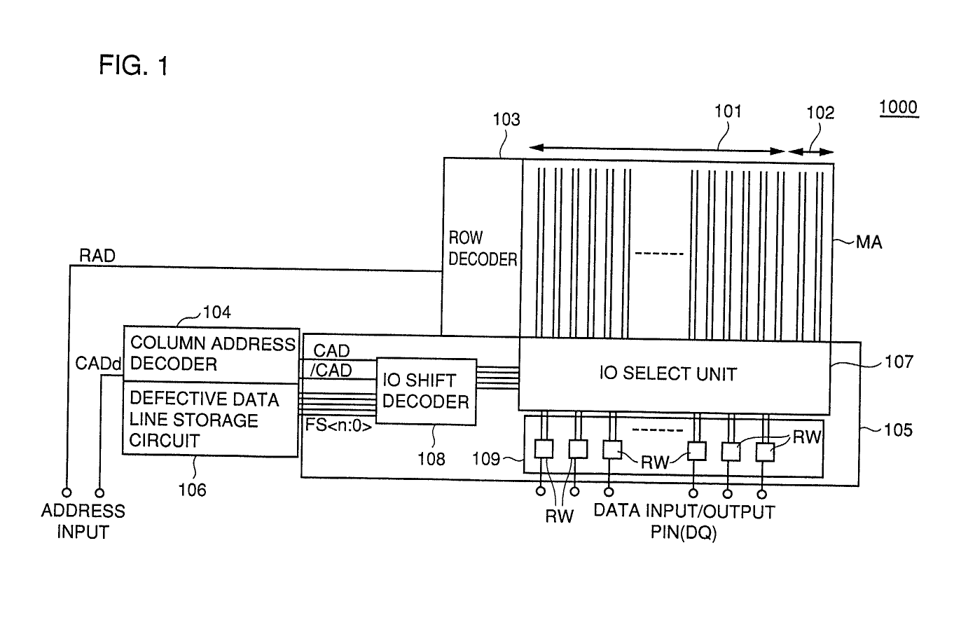

Referring to FIG. 1, a semiconductor memory device 1000 according to a first embodiment of the present invention includes a memory cell array MA. Memory cell array MA includes a plurality of memory cells arranged in a matrix, a plurality of word lines corresponding to rows, and a plurality of bit lines corresponding to columns. Semiconductor memory device 1000 also includes a normal data line pair 101 connected to a memory cell via a sense amplifier, a redundant data line pair 102, a row decoder 103 decoding an input row address RAD to carry out activation (selection in row direction) of a word line select.sense amplifier and the like, a column address decoder 104 decoding an input column address CADd to output column addresses CAD, /CAD, a data line switch circuit 105, and a defective data line storage circuit 106.

Defective data line storage circuit 106 has a structure to identify a defective data line. When a fuse is employed as an example of defective data line storage circuit 106, a defective data line identify signal FS<n:0> (=FS(0)-FS(n)) indicating the presence and position of a defective data line is output according to blowing out or not blowing out the fuse. The structural element of defective data line storage circuit 106 is not limited to a fuse whose status is altered by being blown out or not blown out.

Data line switch circuit 105 includes an IO select unit 107, an IO shift decoder 108, and a read amplifier.write driver unit 109 (IO: Input Output). IO select unit 107 selects a data line pair to be used according to defective data line identify signals FS(0)-FS(n) and the output (select signal SEL) of IO shift decoder 108 receiving column addresses CAD, /CAD. The selected data line pair is electrically coupled to a read amplifier.write driver RW in read amplifier.write driver unit 109.

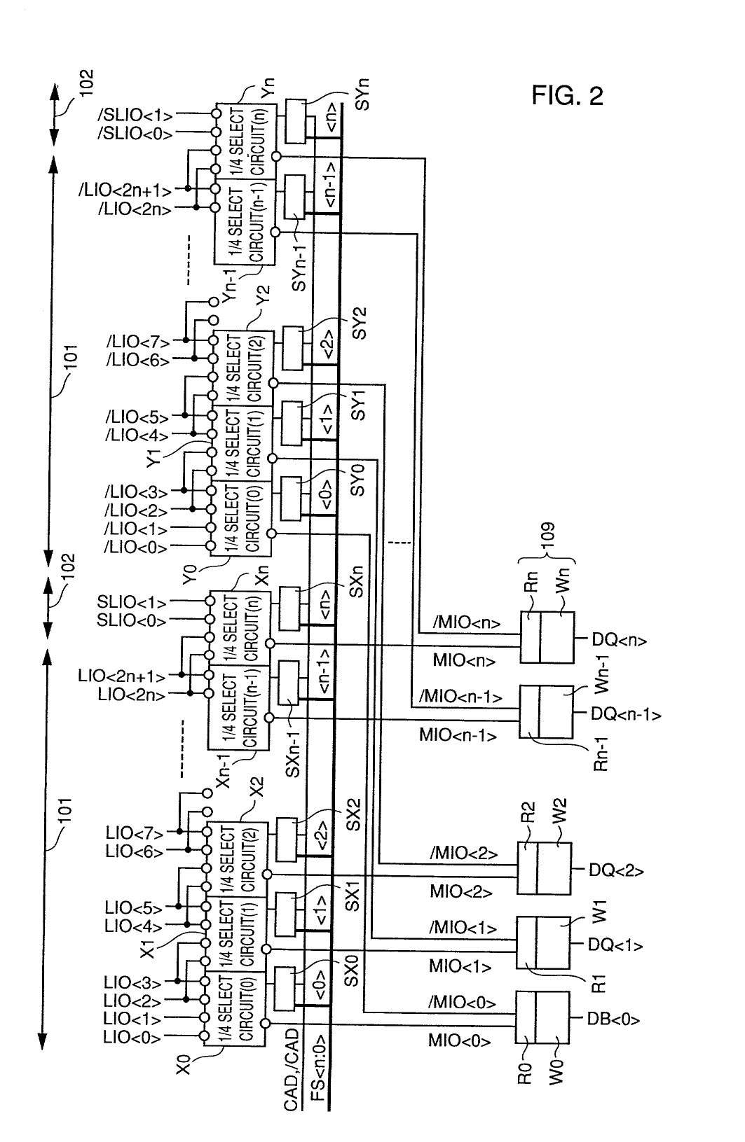

Referring to FIG. 2, LIO(i), /LIO(i) represent normal data line pairs. SLIO(k), /SLIO(k) represent redundant data line pairs (i=0−2n+1, k=0, 1).

(n+1) data line pairs out of the (2n+2) data line pairs are selectively connected to (n+1) main data line pairs MIO(j), /MIO(j) (j=0−n) by IO select unit 107.

IO select unit 107 includes 1/4 select circuits X0-Xn, Y0-Yn selecting one out of four data lines. 1/4 select circuits X0-Xn are disposed corresponding to normal data lines LIO(k) (k=0−2n+1) and redundant data lines SLIO(0), SLIO(1). 1/4 select circuits Y0-Yn are disposed corresponding to normal data lines /LIO(k) (k=0−2n+1) and redundant data lines /SLIO(0), /SLIO(1).

As will be described afterwards, each of 1/4 select circuits X0-Xn and Y0-Yn has the same structure.

1/4 select circuit Xi (i=0−n) selectively connects one of the four data lines with one main data line MIO(i) according to column addresses CAD and /CAD and the select signal output from shift decoder SXi receiving defective data line identify signal FS(i).

1/4 select circuit Yi (i=0−n) selectively connects one of the four data lines with one main data line /MIO(i) according to column addresses CAD and /CAD and the select signal output from shift decoder SYi receiving defective data line identify signal FS(i).

More specifically, 1/4 select circuit X0 connects one of normal data lines LIO(0)-LIO(3) with a main data line MIO(0). 1/4 select circuit Xk connects one of normal data lines LIO(2k)-LIO(2k+3) with a main data line MIO(k) (k=1−n−1). 1/4 select circuit Xn connects one of normal data lines LIO(2n), LIO(2n+1) and redundant data lines SLIO(0), SLIO(1) with a main data line MIO(n). The rules of 1/4 select circuit X0-1/4 select circuit Xn are similarly applied to 1/4 select circuit Y0-1/4 select circuit Yn.

Shift decoders SXi and SYi are included in IO shift decoder 108. It is to be noted that shift decoder SYi can be deleted, and the output of shift decoder SXi shared between 1/4 select circuits Xi and Yi.

Read amplifier.write driver unit 109 includes read amplifiers R0-Rn and write drivers W0-Wn. In a readout operation, read amplifier Ri amplifies differentially the potentials of main data line pair MIO(i), /MIO(i) to provide the amplified result to data input/output pin DQ(i) (external data line DQ(i)) (i=0−n). In a write operation, write driver Wi responds to the data of data input/output pin DQ(i) (external data line DQ(i)) to drive the potentials of main data line pairs MIO(i), /MIO(i) (i=0−n).

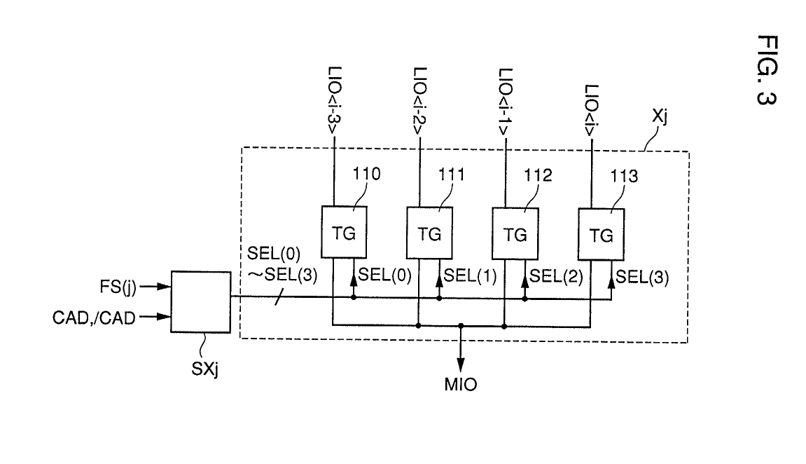

The relationship between the 1/4 select circuit and the shift decoder is shown in FIG. 3. 1/4 select circuit Xj of FIG. 3 includes transfer gates 110-113. In FIG. 3, transfer gates 110-113 are arranged between normal data lines LIO(i-3)-LIO(i) and main data line MIO.

Each of transfer gates 110-113 connects a corresponding data line with the main data line when select signals SEL(0)-SEL(3) attain an H level (logical high). Main data line MIO is connected to read amplifier.write driver unit 109 of FIG. 1.

The potentials of select signals SEL(0)-SEL(3) are determined by shift decoder SXj receiving a defective data line identify signal FS(j), and column addresses CAD, /CAD.

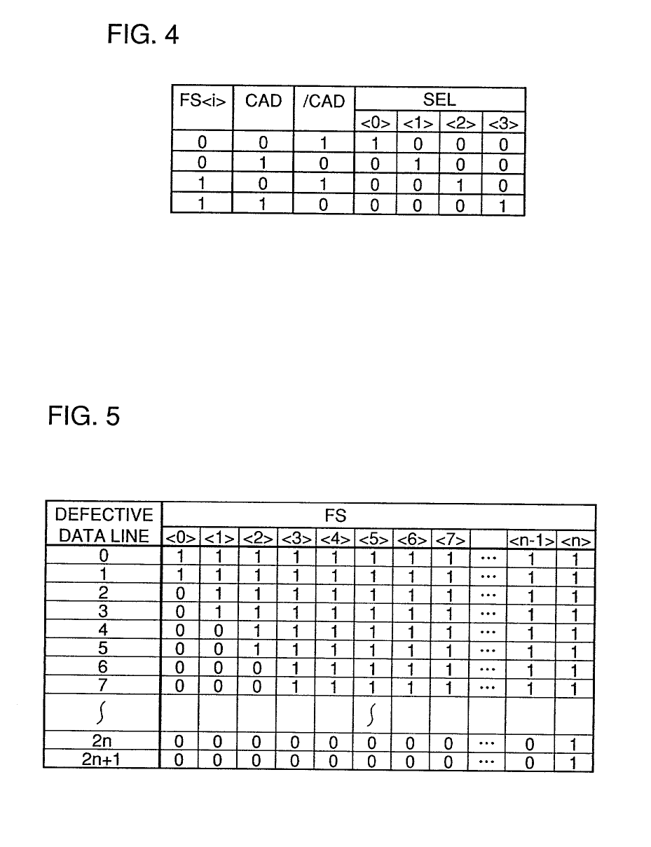

The operation of shift decoders SXi and XYi will be described with reference to FIG. 4. In FIG. 4, “1” represents an H level whereas “0” represents an L level (logical low).

When FS(i)=0, SEL(0)=1 or SEL(1)=1 is established according to the column address. When FS(i)=1, SEL(2)=1 or SEL(3)=1 is established according to the column address.

An example of the relationship between defective data line identify signal FS(i) and a defective data line will be described with reference to FIG. 5. In FIG. 5, “1” represents an H level whereas “0” represents an L level. When normal data line pair LIO(2k), /LIO(2k) or LIO(2k+1), /LIO(2k+1) is defective, defective data line identify signals FS(k)-FS(n) are 1 (shift execution). In other cases, defective data line identify signals FS(k)-FS(n) are 0 (no shift).

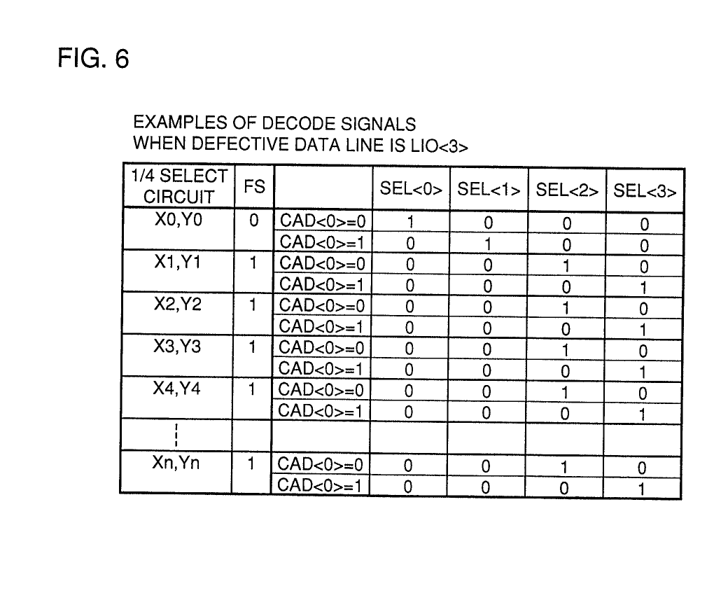

When normal data line LIO(3) is defective, the signal input to each 1/4 select circuit satisfies the relationship of FIG. 6. When normal data line pair LIO(3) is defective, defective data line identify signals FS(1)-FS(n) become 1 and FS(0) becomes 0.

In 1/4 select circuits X0 and Y0, select signal SEL(0) or SEL(1) becomes 1 whereas select signals SEL(2) and SEL(3) become 0. In 1/4 select circuits Xk and Yk, select signals SEL(0), SEL(1) become 0 whereas select signal SEL(2) or SEL(3) becomes 1 (k=1−n).

The selected status of the data line will be described more specifically. It is assumed that normal data line pair LIO(5), /LIO(5) is defective, and cannot be used. In this case, defective data line identify signal FS(i) (i=0, 1) is at an L level and defective data line identify signal FS(j) (j=2−n) is at an H level.

1/4 select circuits X0, X1, Y0 and Y1 receive a defective data line identify signal of an L level. 1/4 select circuits Xj, Yj (j=2−n) receive a defective data line identify signal of an H level.

Therefore, 1/4 select circuit X0 selects normal data line LIO(0) or LIO(1) that is specified by column address CAD. 1/4 select circuit Y0 selects normal data line /LIO(0) or /LIO(1) specified by column address CAD. 1/4 select circuit X1 selects normal data line LIO(2) or LIO(3) specified by column address CAD. 1/4 select circuit Y1 selects LIO(2) or /LIO(3) specified by column address CAD.

1/4 select circuit X2 selects LIO(6) or LIO(7) specified by column address CAD. 1/4 select circuit Y1 selects /LIO(6) or /LIO(7) specified by column address CAD. Therefore, normal data line pair LIO(5), /LIO(5) attains a nonselected state.

Subsequently, 1/4 select circuit Xk (k=3−n−1) selects normal data line LIO(2k+2) or LIO(2k+3) whereas 1/4 select circuit Yk (k=3−n−1) selects normal data line LIO(2k+2) or /LIO(2k+3).

Thus, redundant data line SLIO(0) or SLIO(1) is selected in 1/4 select circuit Xn, and redundant data line /SLIO(0) or /SLIO(1) is selected in 1/4 select circuit Yn.

By combining the column address and the replacement information in the semiconductor memory device of the first embodiment, data line replacement by the data line shift scheme and data line selection can be executed simultaneously. Therefore, high speed data transfer is realized.

Second Embodiment

A semiconductor memory device according to a second embodiment of the present invention will be described here. The second embodiment is a modification of the first embodiment, directed to a semiconductor memory device carrying out redundancy replacement by the data line replacement scheme.

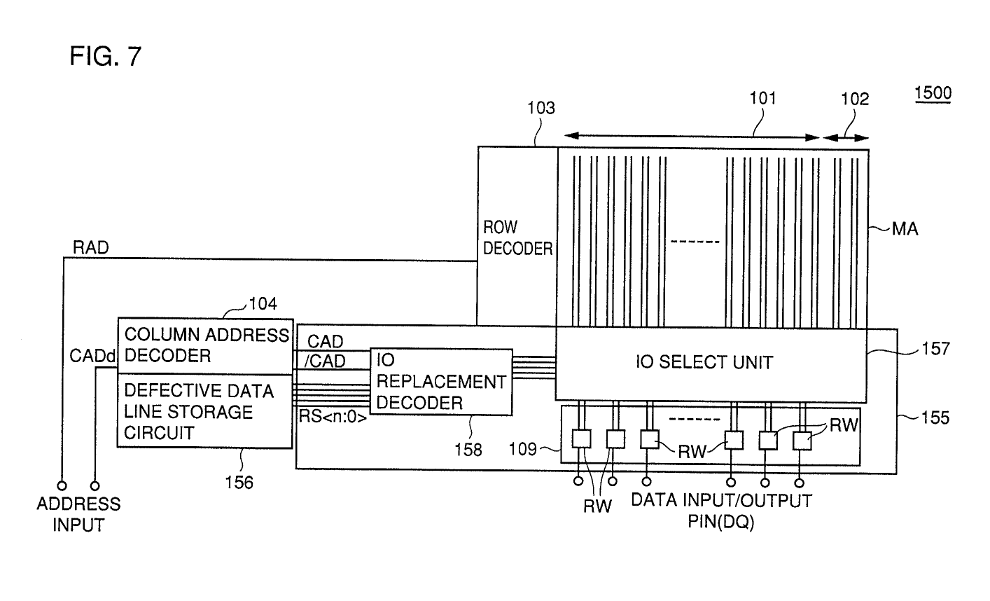

Referring to FIG. 7, a semiconductor memory device 1500 of the second embodiment includes a data line switch circuit 155 instead of data line switch circuit 105, and a defective data line storage circuit 156 instead of defective data line storage circuit 106.

Defective data line storage circuit 156 stores the position information of a defective data line. When a fuse is employed as an example of defective data line storage circuit 156, a defective data line replace signal RS<n:0> (=RS(0)-RS(n)) indicating the replacement information of a defective data line is output according to blow out/nonblow out of the fuse. The structural element of defective data line storage circuit 156 is not limited to a fuse whose status is altered by being blown out or not blown out.

Data line switch circuit 155 includes an I0 select unit 157, an I0 replacement decoder 158, and a read amplifier.write driver unit 109. 10 select unit 157 selects a data line pair to be used according to defective data line replace signals RS(0)-RS(n) and the output (select signal SEL) of IO replacement decoder 158 receiving column addresses CAD and /CAD. The selected data line pair is electrically coupled to a read amplifier.write driver RW in read amplifier.write driver unit 109.

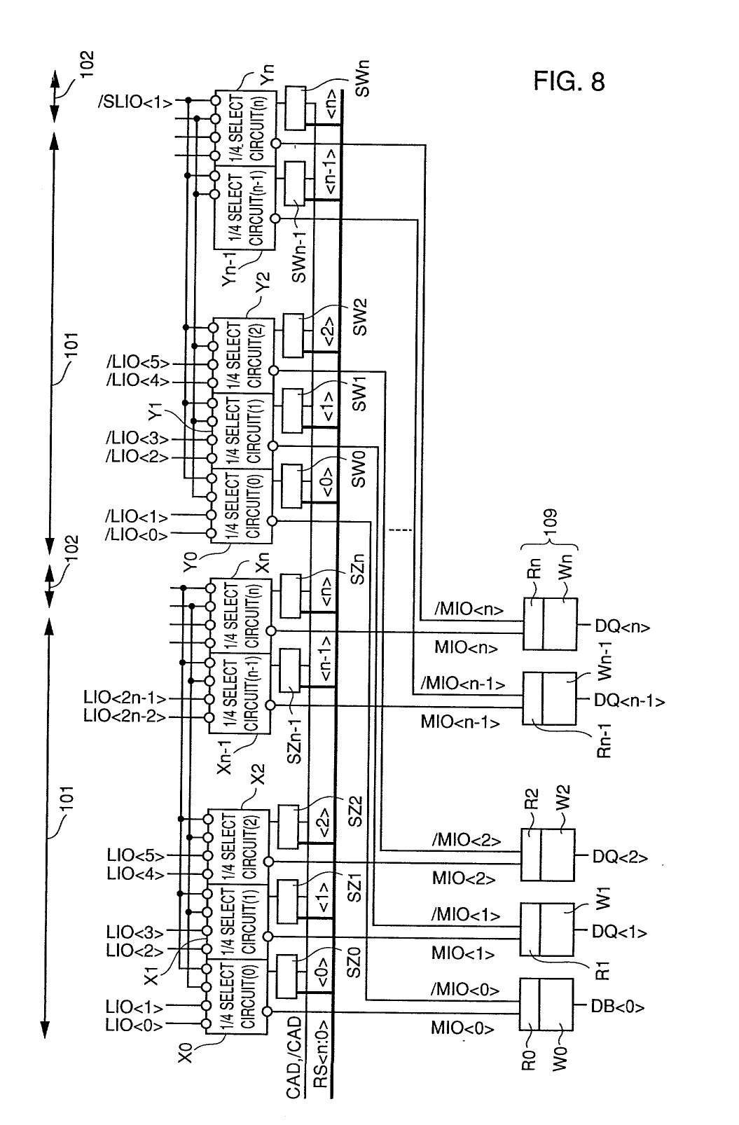

Referring to FIG. 8, LIO(i), ILIO(i) represent a normal data line pair. SLIO(k), /SLIO(k) represent a redundant data line pair (i=0−2n+1, k=0, 1).

(n+1) data line pairs out of the (2n+2) data line pairs are selectively connected to (n+1) main data line pairs MIO), /MIO) (=0−n) by IO select unit 157.

IO select unit 157 includes 1/4 select circuits X0-Xn, Y0-Yn selecting one out of four data lines. In the second embodiment, 1/4 select circuit Xi (i=0−n) selectively connects one of the four data lines with one main data line MIO(i) according to column addresses CAD, /CAD and a select signal output from decoder SZi receiving defective data line replace signal RS(i). 1/4 select circuit Yi (i=0−n) selectively connects one of the four data lines with one main data line /MIO(i) according to column addresses CAD, /CAD and the select signal output from decoder SWi receiving defective data line replace signal RS(i).

1/4 select circuit Xk connects one of normal data lines LIO(2k) and LIO(2k+1) and redundant data lines SLIO(0) and SLIO(1) with main data line MIO(K) (k=0−n).

1/4 select circuit Yk connects one of normal data line /LIO(2k) and /LIO(2k+1) and redundant data lines /SLIO(0) and /SLIO(1) with main data line /MIO(k) (k=0−n).

Decoders SZi and SWi are included in IO replacement decoder 158. It is to be noted that decoder SWi can be removed, and the output of decoder SZi shared in common with 1/4 select circuits Xi and Yi.

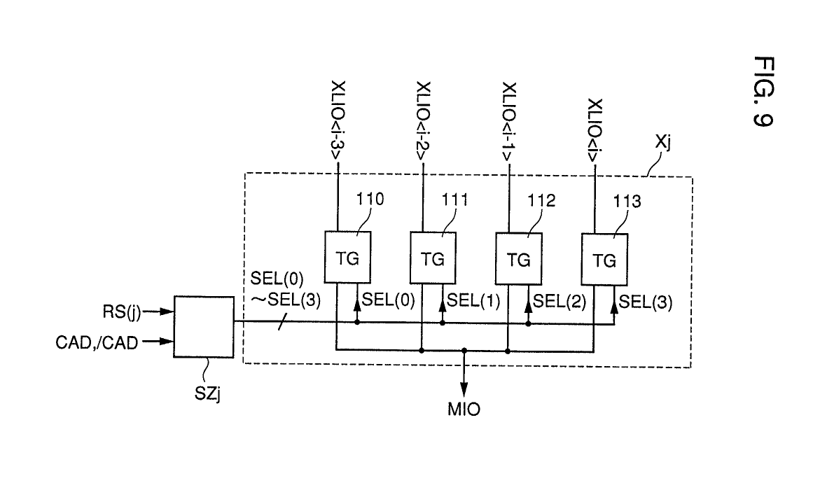

The relationship between the 1/4 select circuit and the decoder is shown in FIG. 9. As described above, 1/4 select circuit Xj includes transfer gates 110-113. Transfer gates 110-113 in 1/4 select circuit Xj of FIG. 9 are disposed between data lines XLIO(i-3)-XLIO(i) and main data line MIO. Each of data lines XLIO(i) and XLIO(i-1) corresponds to redundant data lines SLIO(0) and SLIO(1), respectively. Each of data lines XLIO(i-2) and XLIO(i-3) corresponds to a normal data line.

Each of transfer gates 110-113 connects a corresponding data line with a main data line when select signals SEL(0)-SEL(3) attain an H level.

The potentials of select signals SEL(0)-SEL(3) are determined by decoder SZj receiving defective data line replace signal RS(j) and column addresses CAD, /CAD.

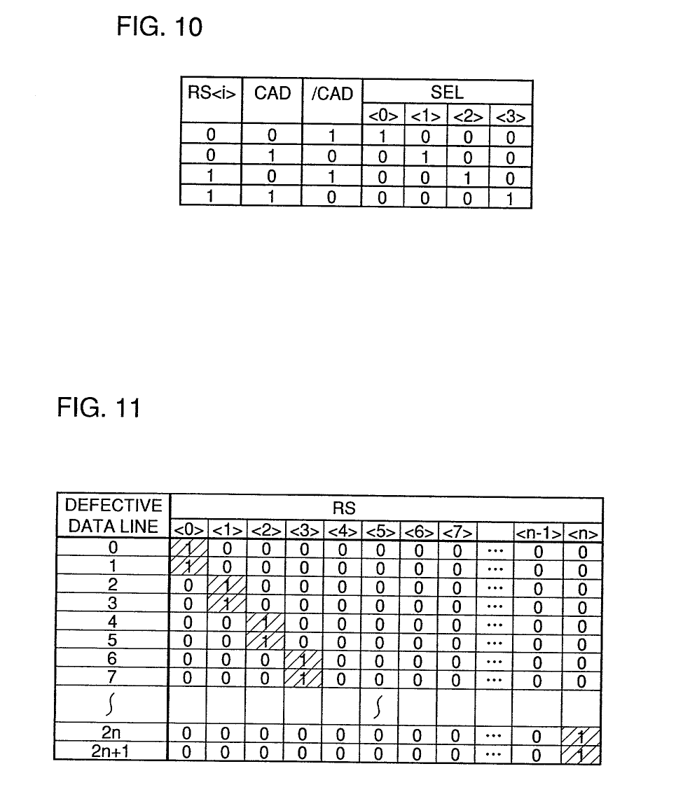

The operation of decoders SZi and SWi will be described with reference to FIG. 10. In FIG. 10, “1” represents an H level whereas “0” represents an L level.

When RS(i)=0, SEL(0)=1 or SEL(1)=1 is established according to the column address. When RS(i)=1, SEL(2)=1 or SEL(3)=1 is established according to the column address.

An example of the relationship between a defective data line replace signal RS(i) and a defective data line will be described with reference to FIG. 11. In FIG. 11, “1” represents an H level whereas “0” represents an L level. When normal data line pair LIO(2k), /LIO(2k) or LIO(2k+1), /LIO(2k+1) is defective, defective data line replace signal RS(k) is “1” (replacement executed), and other defective data line replace signals are “0” (no replacement).

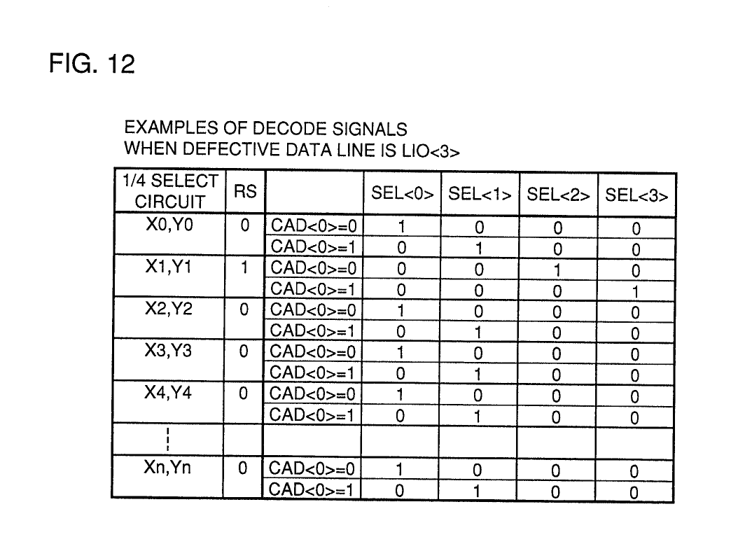

When normal data line LIO(3) is defective, the signal input to each 1/4 select circuit satisfies the relationship of FIG. 12. When normal data line LIO(3) is defective, defective data line replace signals RS(0), RS(2) RS(n) become “0”, and defective data line replace signal RS(1) becomes “1”.

In 1/4 select circuits Xk, Yk (k=0, 2−n), select signal SEL(0) or SEL(1) becomes “1”, and select signals SEL(2), SEL(3) become “0”. In 1/4 select circuits X1 and Y1, select signals SEL(0) and SEL(1) become “0”, and select signal SEL(2) or SEL(3) becomes “1”.

In 1/4 select circuit X1, a redundant data line SLIO(0) or SLIO(1) is electrically connected to main data line MIO(1) instead of the normal data line.

In 1/4 select circuit Y1, redundant data line /SLIO(0) or /SLIO(1) is electrically connected to main data line MIO(1).

In 1/4 select circuit Xk, the normal data line is electrically connected to main data line MIO(1) according to the column address. In 1/4 select circuit Yk, the normal data line is electrically connected to main data line /MIO(1) k=0, 2−n).

By combining the column address and the replacement information in the semiconductor memory device of the second embodiment, data line replacement by the data line replacement scheme and data line selection can be executed simultaneously. Therefore, data transfer of high speed is realized.

Third Embodiment

A semiconductor memory device according to a third embodiment of the present invention will be described. In the third embodiment, the number of normal data line pairs corresponds to 32 (LIO(i), /LIO(i); i=0−31), and the number of the redundant data line pairs corresponds to 1 (SLIO, /SLIO). The data line structure is switchable to x32, x16, x8. In the x16, x8 structure, a data line is selected using the column address.

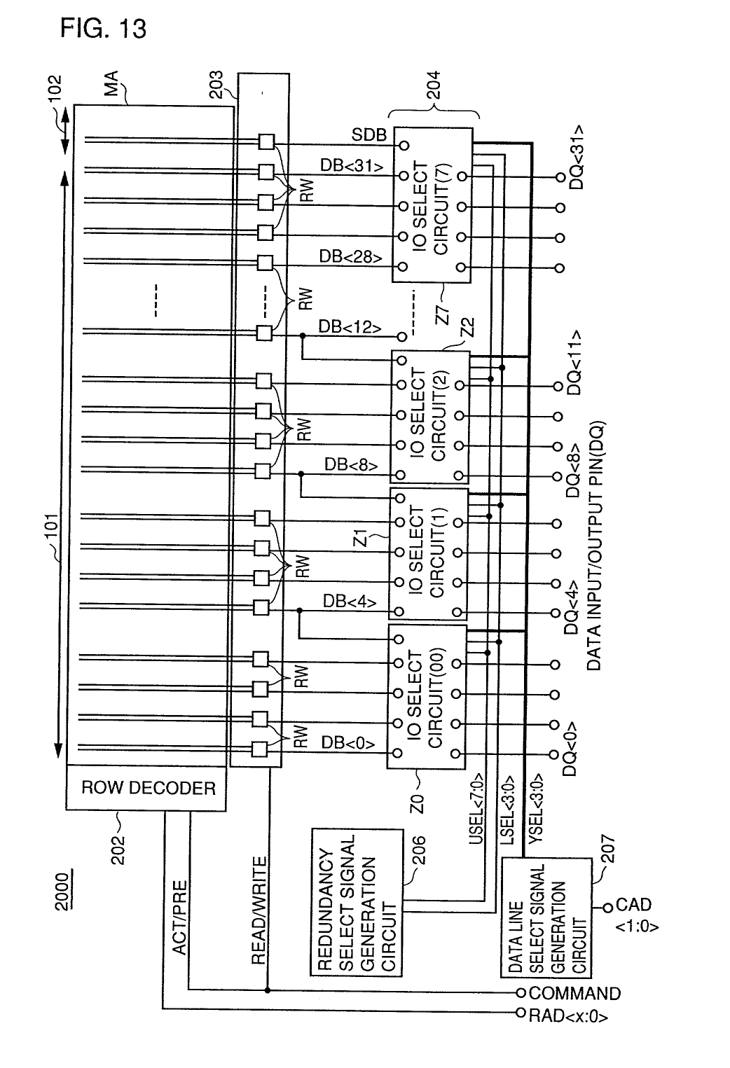

Referring to FIG. 13, a semiconductor memory device 2000 according to the third embodiment includes a memory cell array MA. Memory cell array MA includes a plurality of memory cells arranged in a matrix, a plurality of word lines corresponding to rows, and a plurality of bit lines corresponding to columns. Semiconductor memory device 2000 further includes a normal data line pair 101 connected to a memory cell via a sense amplifier, a redundant data line pair 102, and a row decoder 202 decoding an address RAD(x:0) according to a command (for example, an act command ACT, precharge command PRE) to carry out activation (row select operation) of a word line or a sense amplifier.

Semiconductor memory device 2000 further includes a read amplifier.write driver unit 203 operating according to a command READ/WRITE (write command, read command), an IO select unit 204 with IO select circuits Z0-Z7, a redundancy select signal generation circuit 206, and a data line select signal generation circuit 207.

Read amplifier.write driver unit 203 includes a plurality of read amplifier.write drivers RW provided corresponding to respective data line pairs. The data of each of normal data line pairs LIO(i), /LIO(i) and redundant data line pair SLIO, /SLIO are transferred to internal data line DB(i) and a redundant internal data line SDB via read amplifier.write driver unit 203.

The data of each of internal data line DB(i) and redundant internal data line SDB are transferred to normal data line pair LIO(i), /LIO(i) and redundant data line pair SLIO, /SLIO via read amplifier write driver unit 203.

IO select unit 204 selects an internal data line to be used according to the bus width (column address) and the presence/absence of redundancy usage. Internal data line DB(i) and redundant internal data line SDB are referred to as internal data lines DB(i) and SBD hereinafter.

Internal data lines DB(0)-DB(31), SBD are divided into eight blocks. Each of internal data lines DB(4), DB(8), . . . , DB(28) is shared by adjacent blocks.

IO select circuit Zi (block i) electrically couples the external data line to be used out of external data lines DQ(4i)-DQ(4i+3) with an internal data line to be used out of internal data lines DB(4×1)−DB(4×i+4) (i=0−6). IO select circuit Z7 electrically couples an external data line to be used out of external data lines DQ(28)-DQ(31) with an internal data line to be used out of internal data lines DB(28)-DB(31) and SDB. The external data line and the data input/output pin connected to that external data line are represented by the same reference character.

Redundancy select signal generation circuit 206 stores the position of the normal data line that is required to be replaced, and generates a decode signal according to the stored content. This decode signal is referred to as replacement data line position signal, wherein the upper order bit signals are USEL<7:0> (=USEL(0)-USEL(7)) and the lower order bit signals are LSEL<3:0> (=LSEL(0)-LSEL(3)). Signal LSEL indicates which of the four data lines is defective. Signal USEL indicates the presence of a defective data line in the unit of an IO select circuit.

A fuse is employed to store the position of the data line that is to be replaced. The fuse is blown out (or not blown out) according to the relevant position. The structure of redundancy select signal generation circuit 206 is not limited to a fuse.

Data line select signal generation circuit 207 generates an address decode signal YSEL<3:0> (=YSEL(0)-YSEL(3)) to select a data line according to a column address CAD<1:0> (=CAD(0), CAD(1)).

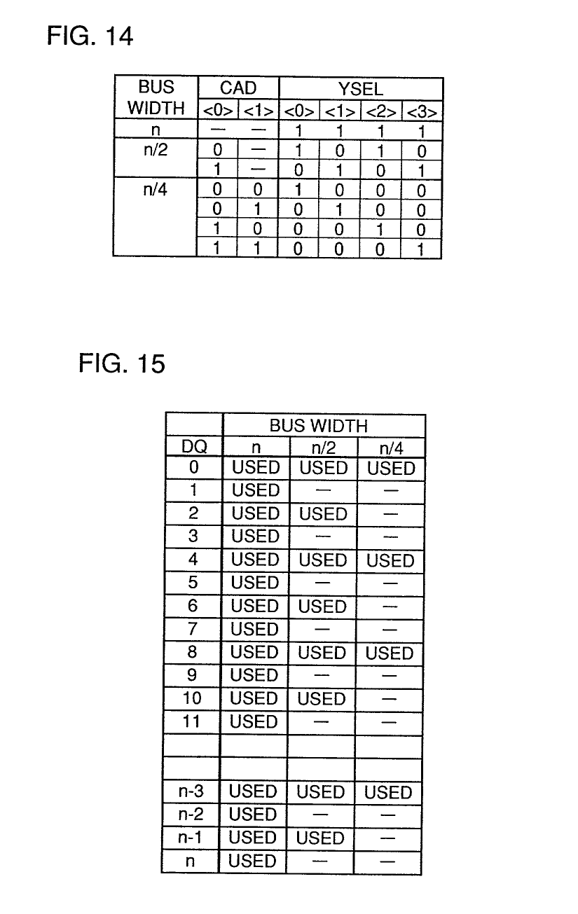

The relationship among the bus width, the column address and address decode signal YSEL<3:0> is as shown in FIG. 14. When the bus width is n, address decode signals YSEL(0)-YSEL(3) are “1” irrespective of the column address. When the bus width is n/2, address decode signals YSEL(0) and YSEL(2) are “1” if column address CAD(0) is “0”, and address decode signals YSEL(1) and YSEL(3) are “1” if column address CAD(0) is “1”. When the bus width is n/4, any one of address decode signals YSEL(0) YSEL(3) becomes “1” according to the (four) combination of column addresses CAD(0) and CAD(1).

The relationship between the bus width and the external data line (data input/output pin) to be used is as shown in FIG. 15. When the bus width is n, all the external data lines are used. When the bus width is n/2, external data lines DQ(i) (i=0, 2, . . . , n−1) is used. When the bus width is n/4, external data line DQ)(j) (j=0, 4, 8, . . . , n−3) is used.

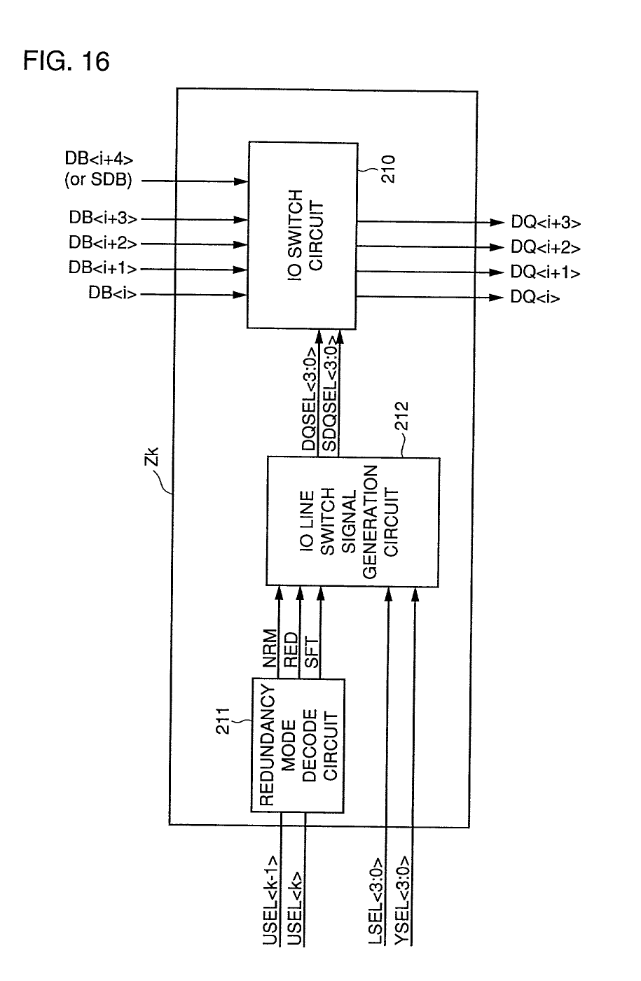

An example of the structure of IO select circuit Zk in IO select unit 204 will be described with reference to FIG. 16. IO select circuit Zk includes an IO switch circuit 210, a redundancy mode decode circuit 211, and an IO line switch signal generation circuit 212. IO switch circuit 210 switches the connection between internal data lines DB(i), DB(i+1), DB(i+2), DB(i+3) and DB(i+4) (or SDB) and external data lines DQ(i), DQ(i+1), DQ(i+2) and DQ(i+3).

The switching by IO switch circuit 210 is under control of select signals DQSEL<3:0> (=DQSEL(0)-DQSEL(3) and SDQSEL<3:0> (=SDQSEL(0)-SDQSEL(3)) output from 10 line switch signal generation circuit 212.

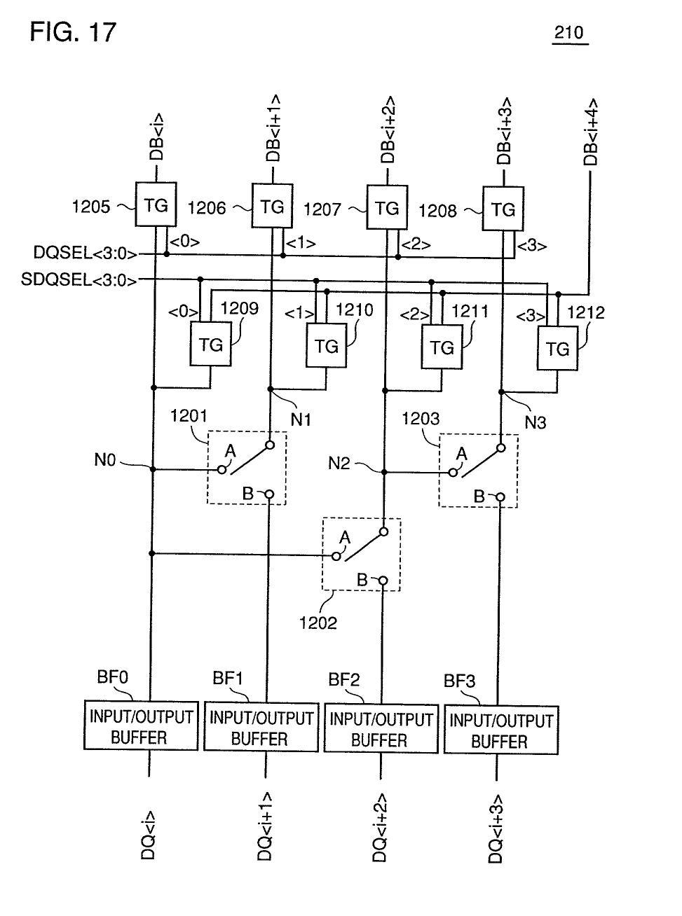

An example of IO switch circuit 210 is shown in FIG. 17. IO switch circuit 210 includes switches 1201-1203, transfer gates 1205-1212, and input/output buffers BF0-BF3 disposed corresponding to external data lines DQ(i)−DQ(i+3).

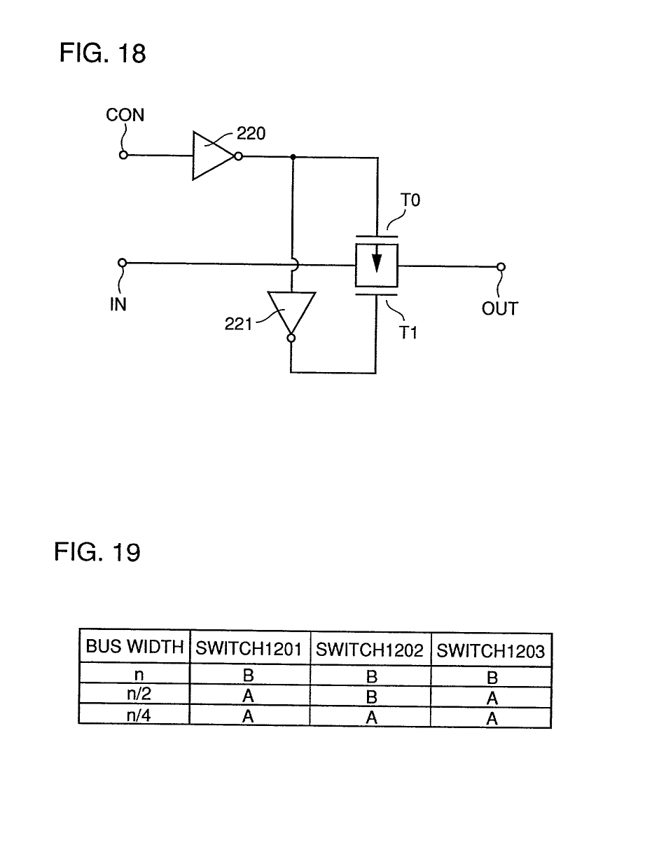

Referring to FIG. 18, transfer gates 1205-1212 include an inverter 220 inverting the control signal received at a node CON, an inverter 221 inverting the output of inverter 220, a PMOS transistor T0 turned on according to the output of inverter 220, and an NMOS transistor T1 turned on according to the output of inverter 221. The ON of transistors T0 and T1 causes the signal received at a node IN to be transmitted to a node OUT.

Referring to FIG. 17, transfer gates 1205-1208 select whether to use or not internal data lines DB(i)-DB(i+3). Transfer gate 1205 couples internal data line DB(i) with node N0 according to a select signal DQSEL(0). Transfer gate 1206 couples an internal data line DB(i+1) with a node N1 according to a select signal DQSEL(1). Transfer gate 1207 couples internal data line DB(i+2) with a node N2 according to a select signal DQSEL(2). Transfer gate 1208 couples internal data line DB(i+3) with a node N3 according to select signal DQSEL(3).

Transfer gates 1209-1212 are used to replace a defective data line using an internal data line DB(i+4) (or SDB) shifted from an adjacent IO select circuit. Transfer gate 1209 couples internal data line DB(i+4) with node N0 according to select signal SDQSEL(0). Transfer gate 1210 couples internal data line DB(i+4) with node N1 according to select signal SDQSEL(1). Transfer gate 1211 couples internal data line DB(i+4) with node N2 according to select signal SDQSEL(2). Transfer gate 1212 couples internal data line DB(i+4) with node N3 according to select signal SDQSEL(3).

Switches 1201-1203 switch the bus line according to the bus width. Switch 1201 couples node N1 with node A (input/output buffer BF0) or node B (input/output buffer BF1) according to the bus width. Switch 1202 connects node N2 with node A (input/output buffer BFO) or node B (input/output buffer BF2) according to the bus width. Switch 1203 connects node N3 with node A (node N2) or node B (input/output buffer BF3) according to the bus width.

More specifically, switches 1201-1203 are switched in the direction shown in FIG. 19 according to the bus width. In FIG. 19, “A” implies that the switch is connected to the node A side whereas “B” implies that the switch is connected to the node B side.

When the bus width is n, nodes N0-N3 are isolated from each other. When the bus width is n/2, nodes N0 and N1 are connected and also nodes N2 and N3 are connected. When the bus width is n/4, node N0 is connected with all nodes N1, N2 and N3.

The switching by switches 1201-1203 can be implemented by electrical switching using transistors, or switching through metal wiring.

Referring to FIG. 16, redundancy mode decode circuit 211 generates a status signal (NRM, RED, SET) using the upper order bit signal (USEL) of the replacement data line position signal. These status signals include information such as whether redundancy replacement is required or not, whether a data line commonly shared with an adjacent block is to be used for redundancy replacement, or whether shifting is to be carried out or not.

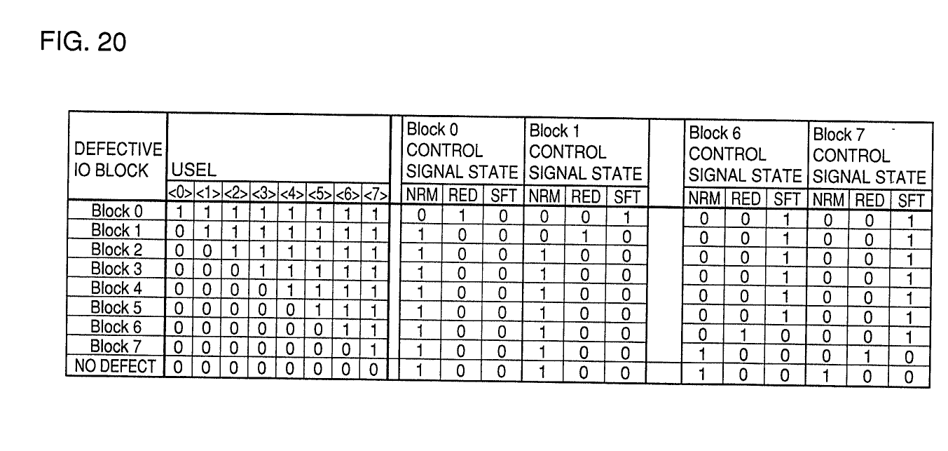

The relationship of the block including the defective data line with respect to signal USEL<7:0> and the status signals NRM, RED, SFT of each block is shown in FIG. 20.

When the defective data line is present in block k (defective data line is any one of the four data lines corresponding to IO select circuit Zk), signals USEL(K+1)-USEL(8) become 1, and the other signals are 0. When there is no defective data line, all the bits of signal USEL<7:0> are 0.

Each block (IO select signal) can take either one of three status, i.e. the status where there is no defect, the status where there is a defect and shifting is to be effected, and the status where shifting is to be effected even though there is no defect.

One of corresponding signals NRM, RED, SFT becomes “1” for each block. When there is a defective data line in block k, signal RED in block k becomes “1” (shift operation is carried out for replacement). In blocks upper of the block with “1” as signal RED, signal SFT becomes “1” (shift operation is carried out), and lower blocks thereof have signal NRM of “1” (normal operation is carried out).

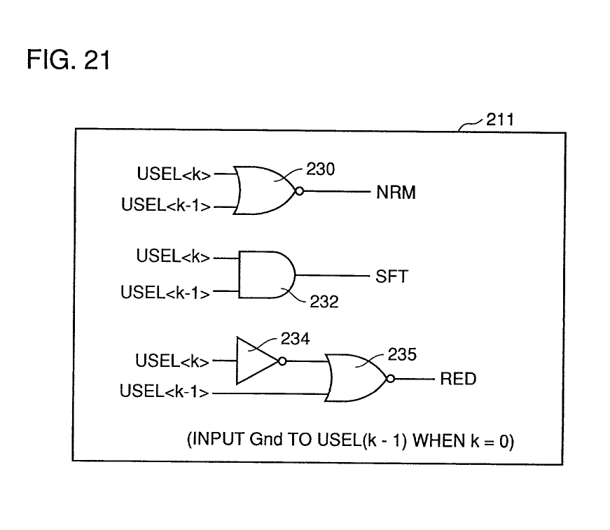

An example of the structure of redundancy mode decode circuit 211 is shown in FIG. 21. Redundancy mode decode circuit 211 includes NOR circuits 230 and 235, an AND circuit 232, and an inverter 234. NOR circuit 230 receives signals USEL(k) and USEL(k−1) to output signal NRM. AND circuit 232 receives signals USEL(k) and USEL(k−1) to output signal SFT. Inverter 234 inverts signal USEL(k). NOR circuit 235 receives the output of inverter 234 and signal USEL(k−1) to output signal RED. When k is 0, ground voltage Gnd is applied to signal USEL(K−1).

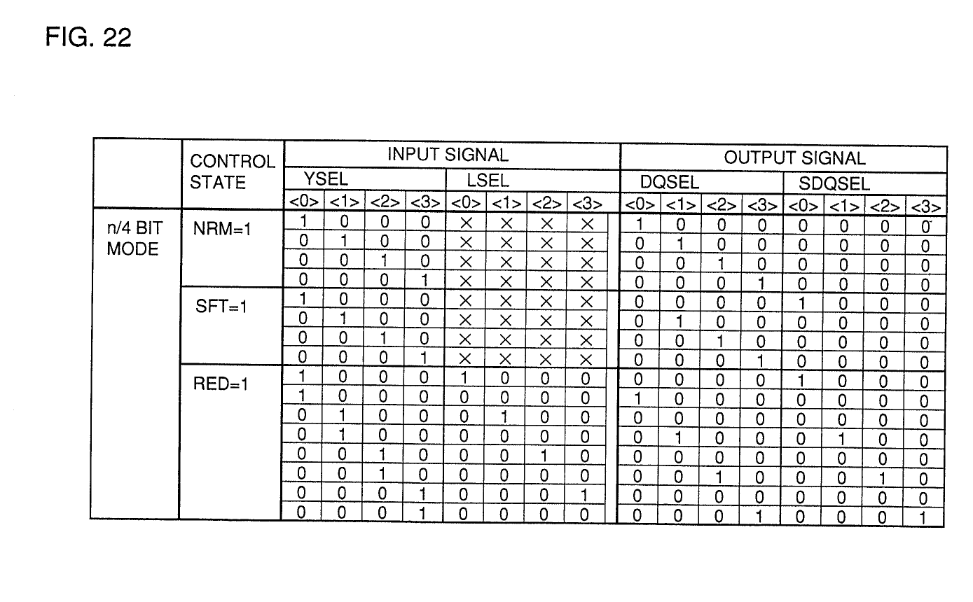

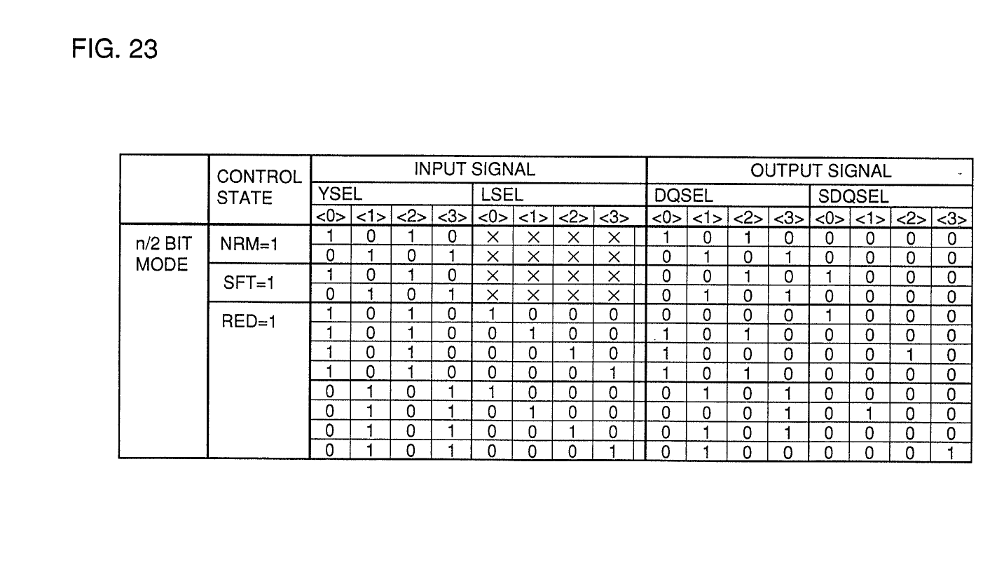

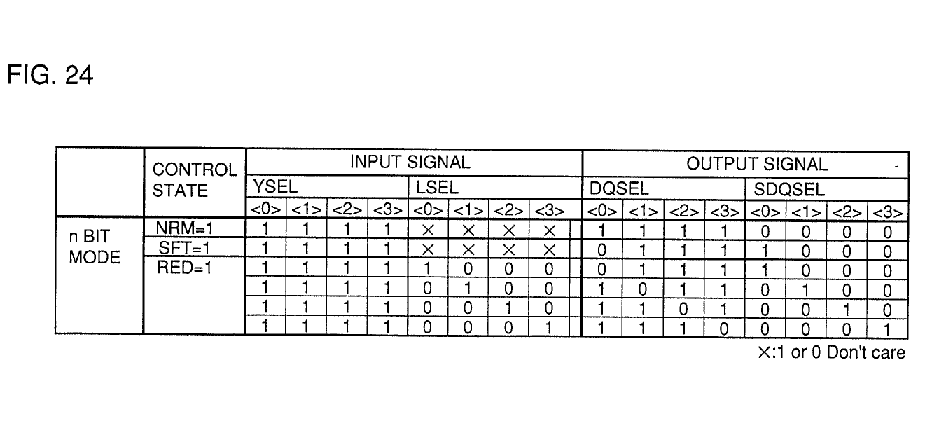

The operation of IO line switch signal generation circuit 212 will be described with reference to FIGS. 22-25. FIGS. 22-24 represent the relationship between the signal input to IO line switch signal generation circuit 212 and output signals DQSEL<3:0>, SDQSEL<3:0>. FIG. 2 corresponds to the n/4 bit mode (bus width is n/4 bits), FIG. 23 corresponds to the n/2 bit mode (bus width is n/2 bits), and FIG. 24 corresponds to the n bit mode (bus width is n bits).

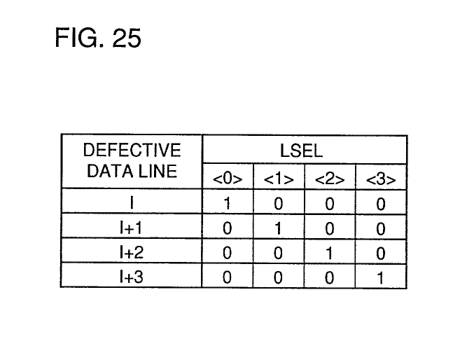

FIG. 25 shows the relationship between the position of the defective data line and signal LSEL<3:0>. Referring to FIG. 25, signal LSEL(k) out of signals LSEL(0)-LSEL(3) becomes “1” when internal data line (i+k) out of internal data lines DB(i)-DB(i+3) belonging to one block is defective.

Referring to FIGS. 22-24, when NMR=1, signals DQSEL(0) DQSEL(3) take values identical to those of signals YSEL(0)-YSEL(3), whereby signals SDQSEL(0)-SDQSEL(3)=0 is established.

When SFT=1, and signal YSEL(0)=1, signal DQSEL(0)=0 is established, and signals DQSEL(1)-DQSEL(3) take values identical to those of signals YSEL(1)-YSEL(3). When SDQSEL(0)=1, SDQSEL(1)-SDQSEL(3)=0 is established. When SFT=1 and YSEL(0)=0, signals DQSEL(0)-DQSEL(3) take values identical to those of signals YSEL(0)-YSEL(3), and signals SDQSEL(O)-SDQSEL(3)=0 is established.

When RED=1, the values of DQSEL(0)-DQSEL(3) and signals SDQSEL(0)-SDQSEL(3) are determined according to signals YSEL and LSEL.

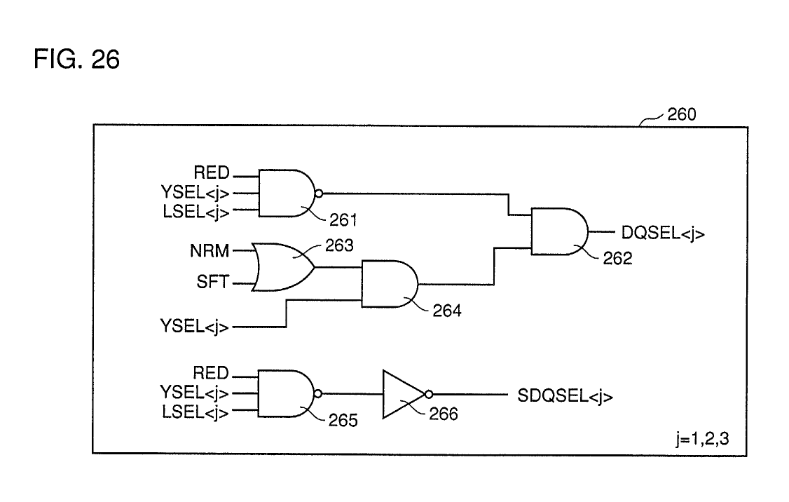

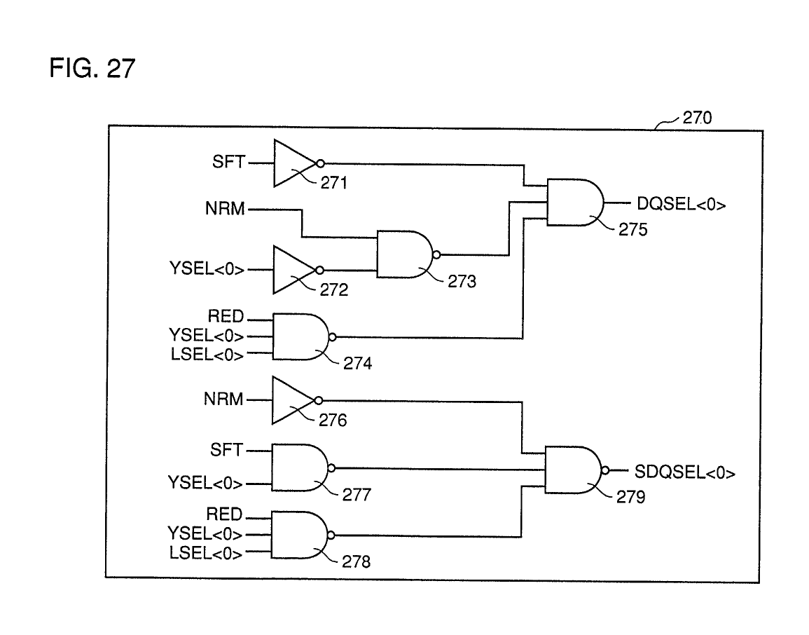

FIGS. 26 and 27 show circuits 260 and 270 in IO line switch signal generation circuit 212. Circuit 260 of FIG. 26 outputs signals DQSEL(j) and SDQSEL(j) (j=1, 2, 3). Circuit 270 of FIG. 27 outputs signals DQSEL(0) and SDQSEL(0).

Circuit 260 includes a NAND circuit 261 receiving signals RED, YSEL(j) and LSEL(j), a NOR circuit 263 receiving signals NRM and SFT, an AND circuit 264 receiving signal YSEL(j) and the output of NOR circuit 263, an AND circuit 262 receiving the outputs of NAND circuit 261 and AND circuit 264 to output signal DQSEL(j), a NAND circuit 265 receiving signals RED, YSEL(j), LSEL(j), and an inverter 266 inverting the output of NAND circuit 265 to output a signal SDQSEL(j).

Circuit 270 includes an inverter 271 receiving and inverting signal SFT, an inverter 272 receiving and inverting signal YSEL(0), a NAND circuit 273 receiving signal NRM and the output of inverter 272, a NAND circuit 274 receiving signals RED, YSEL(0) and LSEL(0), and an AND circuit 275 receiving the outputs of inverter 271, NAND circuit 273 and NAND circuit 274 to output signal DQSEL(0).

Circuit 270 further includes an inverter 276 inverting signal NRM, a NAND circuit 277 receiving signals SFT and YSEL(0), a NAND circuit 278 receiving signals RED, YSEL(0) and LSEL(0), and an AND circuit 279 receiving the outputs of inverter 276, NAND circuit 277 and NAND circuit 278 to output signal SDQSEL(0).

The operation of semiconductor memory device 2000 will be described based on the example where “x8” is specified as the data line configuration. It is assumed that there is a defect in the memory cell corresponding to normal data line LIO(5), and normal data line LIO(5) is to be replaced.

Upon input of an act command ACT, the word line is rendered active according to row address RAD<x:0> that is input at the same time. The data of the memory cell is held in the sense amplifier. Complementary data signals are transmitted to all normal data line pairs LIO, /LIO and redundant data line pair SLIO, /SLIO.

When read command READ is input, the read amplifier is rendered active, and the data is transferred to internal data lines DB and SDB.

In the data line configuration of “x8”, the external data lines (data input/output pin) to be used are DQ(0), DQ(4), DQ(8), . . . , DQ(28). In order to determine the eight internal data lines to be used out of the 32 regular internal data lines, signal YSEL<3:0> is generated according to the 2-bit column address CAD(0), CAD(1) input simultaneous to read command READ.

Replacement data line position signals USEL, LSEL are fixed signals, determined before a column operation. The control signal of each IO select circuit is switched according to signals YSEL, USEL, and LSEL, whereby internal data lines DB and SDB are connected with external data line DQ.

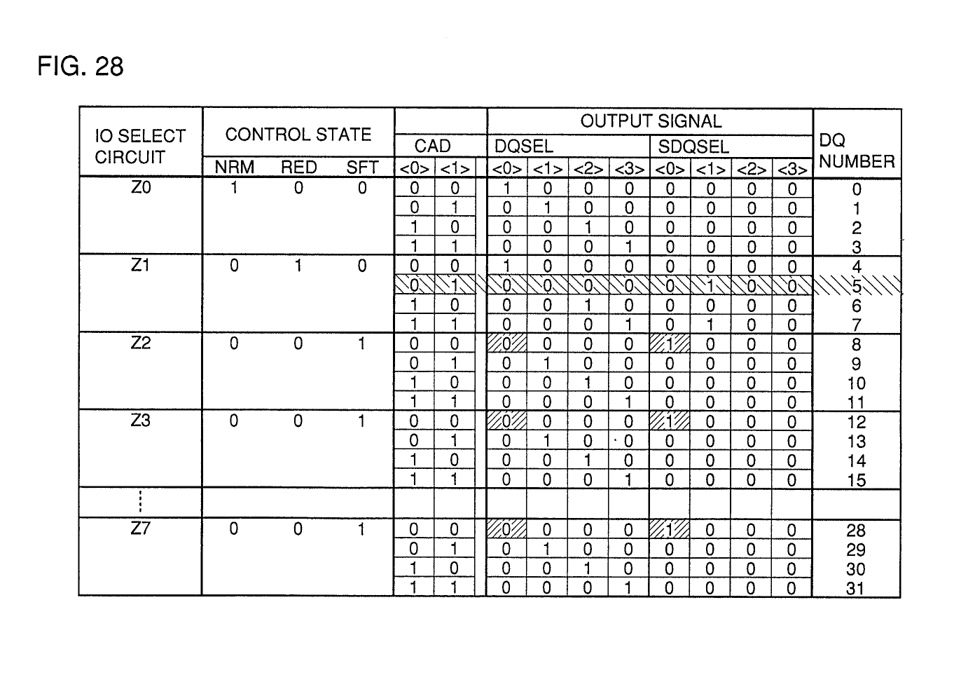

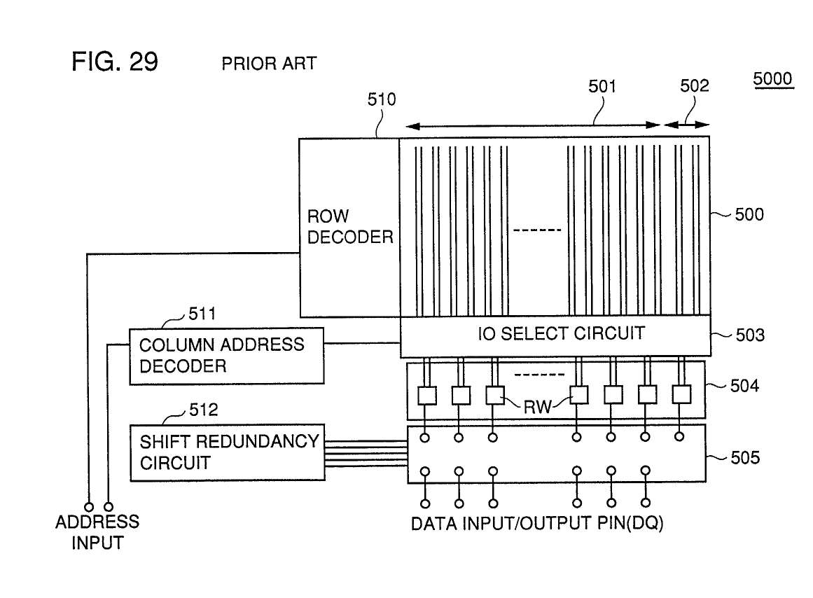

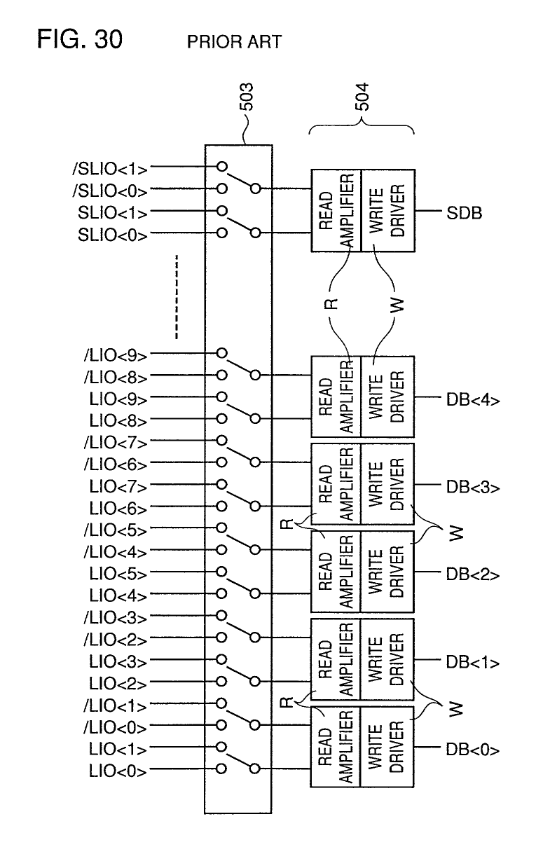

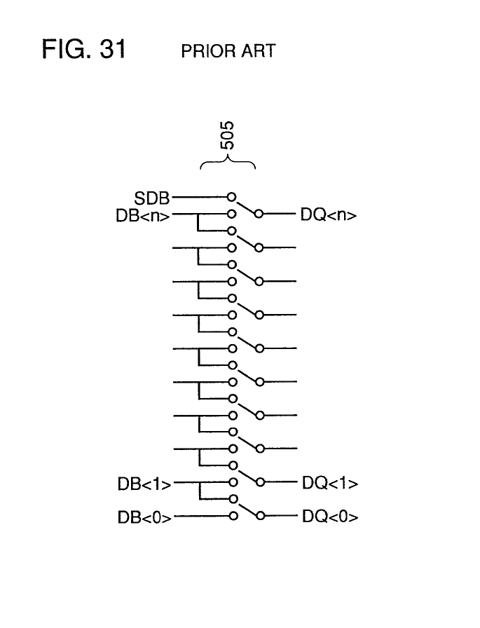

The status of the control signal of each IO select circuit is shown in FIG. 28. Since the data line to be replaced is LIO(5), redundancy replacement is required in IO select circuit Z1. Status signal RED of IO select circuit Zl becomes “1”.

Since internal data line DB(i+1) shown in FIG. 17 is the data line that is to be replaced in IO select circuit Z1, signal DQSEL(1) is fixed to L. Signal SDQSEL(1) indicating the replacement position becomes H only when column address CAD<1:0>=“01”, otherwise to L. Signals DQSEL(0), DQSEL(2), and DQSEL(3) have their values determined according to the decode of column address CAD<1:0>. Signals SDQSEL(0), SDQSEL(2), and SDQSEL(3) are fixed at the L level.

A block lower than block 1 (IO select circuit Z1), i.e. IO select circuit ZO, does not have to shift the internal data line. Therefore, the number assigned to internal data line DB and external data line DQ is identical. In IO select circuit ZO, signal NRM is “1”. In this block, all signals SDQSEL are fixed to the L level, and one of signals DQSEL is driven to an H level according to CAD<1:0>.

In block 1, an internal data line DB(8) that is shared with block 2 (IO select circuit Z2) is used as the redundant data line. Therefore, block 2 uses internal data line DB(12) shared with the adjacent block. Blocks 3-7 (IO select circuits Z3-Z7) carry out a similar operation. More specifically, connection of the data lines is shifted. In IO select circuits Z2-Z7, status signal SFT is “1”.

In the structure of FIG. 17, internal data lines DB(i+4), DB(i+1), DB(i+2), DB(i+3) are sequentially connected to nodes N0-N3, and the usage of internal data line DB(i) is disabled. More specifically, when column address CAD<1:0>=“00”, signal SDQSEL(O) attains an H level and signal DQSEL(O) attains an L level. The internal data line shared with the adjacent block is replaced with internal data line DB(i). In other cases, signal DQSEL corresponds to column address CAD, and signal SDQSEL is fixed at an L level.

In a write operation, the data line is switch in a manner similar to that of a readout operation. In IO select unit 204, the input 8-bit write data is converted into 32 bits while the defective data line is replaced with a redundant data line. Then, the write data is written into the memory cell via the sense amplifier.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a memory cell array including a plurality of memory cells arranged in a matrix;
a plurality of data lines including a redundant data line and a normal data line to read out data from said memory cell array or write data into said memory cell array;
a plurality of external data lines to transfer data with an external source; and
a data line switch circuit executing simultaneously a select operation of selecting a data line to be coupled with said plurality of external data lines and a shift operation of shifting connection between said plurality of external data lines and said data line to be coupled according to an external address and data line information related to a defective data line in said normal data line.

2. The semiconductor memory device according to claim 1, wherein said plurality of data lines are divided into a plurality of blocks,
said data line switch circuit including
a decoder decoding said external address and said data line information, and
a plurality of select circuits respectively disposed between said plurality of blocks and said plurality of external data lines,
wherein said plurality of select circuits respectively share some data lines with adjacent select circuits, and carry out simultaneously said select operation and said shift operation according to an output of said decoder.

3. The semiconductor memory device according to claim 2, wherein each of said plurality of select circuits comprises a plurality of transfer gates provided between a corresponding data line and a corresponding external data line, open and closed according to an output of said decoder.

4. A semiconductor memory device comprising:
a memory cell array including a plurality of memory cells arranged in a matrix;
a plurality of data lines including a redundant data line and a normal data line to read out data from said memory cell array or write data into said memory cell array;
a plurality of external data lines to transfer data with an external source; and
a data line switch circuit executing simultaneously a select operation of selecting a data line to be coupled with said plurality of external data lines according to an external address and a replacement operation of replacing a defective data line in said data line to be coupled with said redundant data line according to data line information related to the defective data line included in said normal data line.

5. The semiconductor memory device according to claim 4, wherein said plurality of normal data lines are divided into a plurality of blocks,
said data line switch circuit including
a decoder decoding said external address and said data line information, and
a plurality of select circuits respectively disposed corresponding to said plurality of blocks,
wherein said plurality of select circuits respectively carry out simultaneously said select operation and said replacement operation.

6. The semiconductor memory device according to claim 5, wherein each of said plurality of select circuits comprises a plurality of transfer gates provided between said redundant data line and said corresponding normal data line and a corresponding external data line, open and closed according to an output of said decoder.

7. A semiconductor memory device comprising:
a memory cell array including a plurality of memory cells arranged in a matrix;
a plurality of data lines including a redundant data line and a normal data line to read out data from said memory cell array or writing data into said memory cell array;
a plurality of external data lines to transfer data with an external source; and
a data line switch circuit executing simultaneously a select operation of selecting a data line to be coupled with an external data line to be used according to a bus width and a shift operation of shifting connection between said external data line to be used and said data line to be coupled according to data line information related to a defective data line in said normal data line.

8. The semiconductor memory device according to claim 7, wherein each of said plurality of data lines and said plurality of external data lines is divided into a plurality of blocks,
said plurality of blocks sharing some data lines with an adjacent block,
said data line switch circuit including a plurality of switch circuits arranged corresponding to each of said plurality of blocks,
wherein each of said plurality of switch circuits belong to any status of a first mode switching connection between a corresponding data line and a corresponding external data line according to said bus width, a second mode of replacing said defective data line with said shared data line, and shifting connection between said corresponding external data line and said corresponding data line according to said bus width, and a third mode of shifting connection between a corresponding external data line and a corresponding data line according to said bus width.

9. The semiconductor memory device according to claim 8, wherein each of said plurality of switch circuits comprises
m nodes,
a first gate selectively switching connection between said m nodes and m external data lines according to said bus width,
a second gate rendering said defective data line and said m nodes nonconnected according to said bus width and said data line information, and
a third gate selectively connecting said shared data line with one of said m nodes according to said bus width and said data line information.
